(19) United States
(12) Patent Application Publication
(10) Pub. No.: US 2002/0139304 A1
(43) Pub. Date: Oct. 3, 2002

(54) Semiconductor manufacturing apparatus

(75) Inventor: Tadashi Terasaki, Nakano-ku (JP)

Correspondence Address: OLIFF & BERRIDGE, PLC, P.O. BOX 19928, ALEXANDRIA, VA, 22320, US

(73) Assignee: HITACHI KOKUSAI ELECTRIC INC., TOKYO (JP)

(21) Appl. No.: 10/105,437

(22) Filed: Mar. 26, 2002

(30) Foreign Application Priority Data
Mar. 27, 2001 (JP) 2001-091224
Feb. 18, 2002 (JP) 2002-40384

(51) Int. Cl. C23C 16/00

(52) U.S. Cl. 118/723 E; 118/725; 118/666

(57) ABSTRACT

A semiconductor manufacturing apparatus can sufficiently increase a nitrogen concentration in a nitride compound thin film, and make a low temperature nitrify treatment possible. The apparatus comprises a vacuum vessel 21 wherein a nitride film is formed by a plasma treatment. A nitrify raw material gas is introduced into the vessel from a gas supply opening 26 through a gas introduction system 41. The vessel is exhausted from an exhaustion opening 34 and a pressure in the vessel is controlled by a vacuum exhaustion system 42. A magnetic force line generator 31 and a tube-shaped discharge electrode 29 which is connected to a high-frequency electric power application system 43 are provided along an outer periphery of the vessel so that the gas is allowed to discharge by an electric field and magnetic force lines H thereby forming a high-density plasma within a plasma treatment region 20. In an interior of the vessel, there is provided a susceptor 33 on which a substrate W to be treated. The susceptor is provided with a ceramic heater for heating the substrate. The heater is controlled by a heat controller so that a temperature of the substrate is controlled to be 400° C. or lower.

### BACKGROUND OF THE INVENTION

1. Field of the Invention

This invention relates to a semiconductor manufacturing apparatus, and particularly to a plasma film formation apparatus for forming a nitride film on a substrate to be treated within a vacuum vessel.

2. Description of the Related Art

In a process for manufacturing a semiconductor device such as an LSI. a nitrify treatment is performed that forms a thin film of a nitride film in order to improve an element quality. For example, in a process for forming a gate insulation film, nitrogen (N) is incorporated into a silicon oxide film (SiO) to form a silicon oxynitride (SiON) film, in order to prevent an element quality from being deteriorated due to diffusion of boron from a Poly-Si of a gate electrode to a channel region, or in order to increase a dielectric constant of a gate insulation film to enhance a channel electric current. In a process for forming a Ta₂O₅ capacitor, a nitrify treatment is performed on a surface of a Poly-Si film to form a silicon nitride film in order to prevent a value of capacitance from being increased due to diffusion of the oxygen in the Ta₂O₅ film into the Poly-Si film which is a lower electrode.

A technique of these nitrify treatments which is a RTN (Rapid Thermal Nitridation) method is performed by exposing a substrate to be treated of a semiconductor device to an atmosphere of a nitrogen gas or a nitrogen-containing compound gas at a high temperature of 800° C. or higher.

In the above-mentioned vitrify treatment technique, however, a nitrogen concentration in the thin film of the nitride compound can not be increased sufficiently so that it is difficult to improve a quality of the device. Additionally, in the nitrify treatment of the Ta₂O₅ capacitor, because a quality of a MOS transistor is deteriorated due to accumulation of a thermal history, there is a need for a low temperature nitrify treatment.

### SUMMARY OF THE INVENTION

An object of the present invention is to provide a semiconductor manufacturing apparatus wherewith, by resolving the problems with the prior art noted in the foregoing, a nitrogen concentration in a thin film of a nitride compound can be increased sufficiently, and moreover, a low temperature nitrify treatment is possible.

A first invention is a semiconductor manufacturing apparatus for forming a nitride film, comprising: a vacuum vessel having a plasma treatment region established in an interior thereof for treating a substrate to be treated; a gas introduction system for introducing a nitrogen or a nitrogen-containing compound gas into vacuum vessel; a tube-shaped discharge electrode disposed along an outer periphery of the vacuum vessel for generating an electric field in the plasma treatment region and causing a compound gas introduced into the vacuum vessel to discharge; a high-frequency electric power application system for applying high-frequency electric power to the tube-shaped discharge electrode to generate the electric field; a magnetic force line generator, disposed along an outer periphery of the vacuum vessel, that generates magnetic force lines in the plasma treatment region and causing the magnetic force lines to capture electric charges generated by the discharge; a vacuum exhaustion system for exhausting the vacuum vessel and controlling a pressure in the vacuum vessel; a heater that heats the substrate to be treated within the vacuum vessel; and a heat controller that controls the heater such that a temperature of the substrate to be treated is 400° C. or lower.

As in the present invention, in the case of forming a nitride film by using a semiconductor manufacturing apparatus wherein an electric field and a magnetic field are generated in a plasma treatment region and a plasma discharge is accelerated, a temperature of a substrate to be treated is preferably controlled to be 400° C. or lower. This is because, if the temperature of the substrate to be treated is higher than 400° C., a nitrify rate is decreased. Since the nitrify rate is decreased even in the case that the temperature of the substrate to be treated is lower than 150° C., the temperature of the substrate to be treated is preferably controlled to be within the range of 150° C. to 400° C. where the nitrify rate is increased. In order to maintain the nitrify rate at its maximum, the temperature of the substrate to be treated is preferably controlled to be within the range of 240° C. to 340° C.

A second invention is a semiconductor manufacturing apparatus for forming a nitride film, comprising: a vacuum vessel having a plasma treatment region established in an interior thereof for treating a substrate to be treated; a gas introduction system for introducing a nitrogen or a nitrogen-containing compound gas into the vacuum vessel; a tube-shaped discharge electrode disposed along an outer periphery of the vacuum vessel for generating an electric field in the plasma treatment region and causing a compound gas introduced into the vacuum vessel to discharge; a high-frequency electric power application system for applying high-frequency electric power to the tube-shaped discharge electrode to generate the electric field; a magnetic force line generator, disposed along an outer periphery of the vacuum vessel, that generates magnetic force lines in the plasma treatment region and causing the magnetic force lines to capture electric charges generated by the discharge; a vacuum exhaustion system for exhausting the vacuum vessel and controlling a pressure in the vacuum vessel such that the pressure in the vacuum vessel is 80 Pa or lower; a heater that heats the substrate to be heated within the vacuum vessel; and a heat controller that controls a temperature of the substrate to be treated by controlling the heater.

As in the present invention, in the case of forming a nitride film by using a semiconductor manufacturing apparatus wherein an electric field and a magnetic field are generated in a plasma treatment region and a plasma discharge is accelerated, a pressure in the vacuum vessel is preferably controlled to be 80 Pa or lower. Since if the pressure in the vacuum vessel is higher than 80 Pa, the nitrify rate is decreased, the pressure in the vacuum vessel is preferably controlled to be within the range of 80 Pa or lower where the nitrify rate is increased.

### BRIEF DESCRIPTION OF THE INVENTION

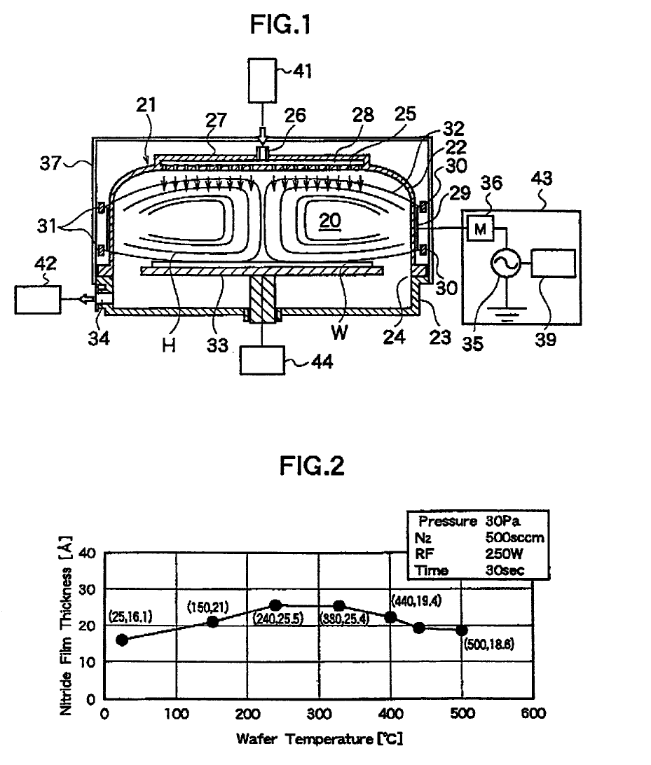

FIG. 1 is a schematic sectional view of a modified magnetron high-frequency discharge type plasma treatment apparatus (MMT apparatus) according to an embodiment;

FIG. 2 is a view for illustrating a relation between a wafer temperature and a nitride film thickness according to an embodiment;

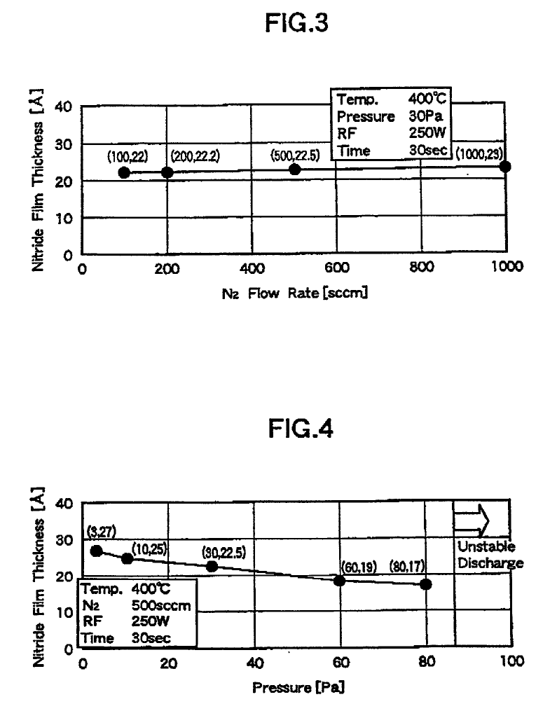

FIG. 3 is a view for illustrating a relation between a nitrogen flow rate and a nitride film thickness according to an embodiment;

FIG. 4 is a view for illustrating a relation between a pressure and a nitride film thickness according to an embodiment;

FIG. 5 is a view for illustrating a relation between high-frequency (RF) electric power and a nitride film thickness according to an embodiment;

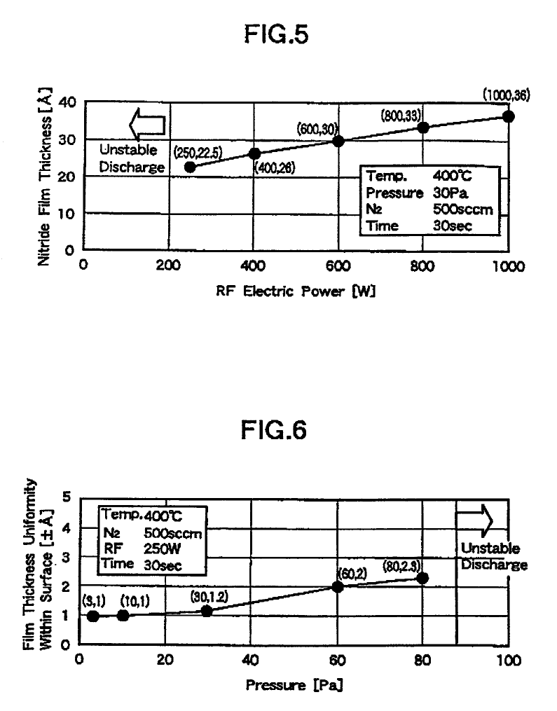

FIG. 6 is a view for illustrating a relation between a pressure and film thickness uniformity within a surface according to an embodiment;

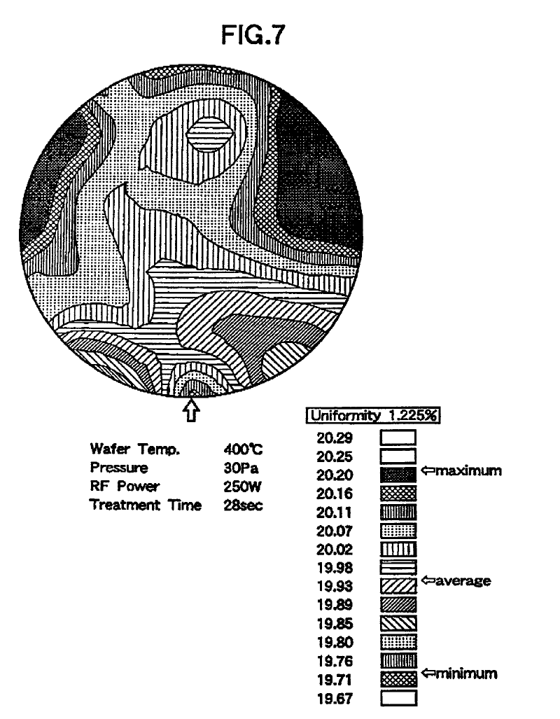

FIG. 7 is a view for illustrating a nitride film thickness distribution according to an embodiment;

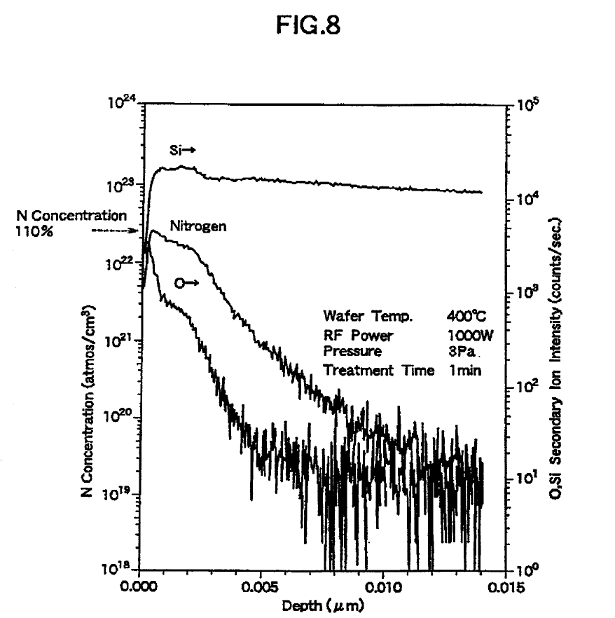

FIG. 8 is a profile of nitrogen N in an SiO₂ film according to an embodiment;

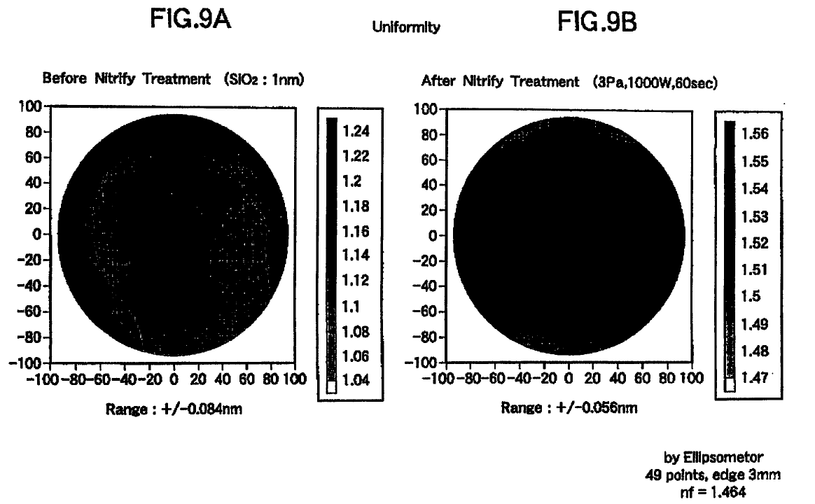

FIG. 9 is a view for illustrating an SiO₂ film distribution before a nitrify treatment according to an embodiment and a nitride film distribution after the nitrify treatment; and

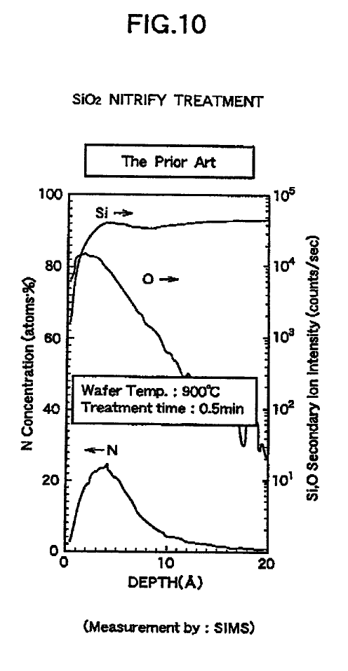

FIG. 10 is a profile of nitrogen N in the conventional example.

### DESCRIPTION OF THE PREFERRED EMBODIMENTS

Embodiments where a semiconductor manufacturing apparatus of the present invention is applied to a modified magnetron high-frequency discharge type plasma treatment apparatus (hereinafter simply referred to as an MMT apparatus) will be explained below.

(1) Apparatus Construction

FIG. 1 shows a schematic sectional view of a plasma treatment apparatus. A vacuum vessel 21 comprises a upper vessel 22 and a lower vessel 23. The upper vessel 22 is of a dome shape which is one piece structure without a juncture except that the upper vessel 22 is opened at its lower end. The lower vessel 23 is also one piece structure without a juncture except that the lower vessel 23 is opened at its upper end. A lower opening portion 24 of the upper vessel 22 is sealed by the lower vessel 23 via a sealing member such as an O-ring and the like (not shown) to maintain a vacuum so that a plasma treatment region 20 is formed in an interior of the vacuum vessel 21. The vacuum vessel 21 is formed of a dielectric such as quartz, ceramic, aluminum oxide (alumina) and the like. If the vacuum vessel 21 is forted of a dielectric, a temperature of a wall of the vacuum vessel 21 can be adjusted to a relatively high temperature as required. As a result, particles which occur on the wall of the vacuum vessel 21 during a process can be reduced.

At an upper portion of the vacuum vessel 21, a plurality of shower apertures 25 are formed that eject in a form like a shower a gas which is supplied into the plasma treatment region 20. This allows a gas flow supplied into the vacuum vessel 21 to be uniform thereby improving uniformity of the plasma treatment on a substrate to be treated W. Since the vacuum vessel 21 in which the gas shower apertures 25 are formed is composed of a dielectric, metal contamination from the gas shower apertures 25 can be extremely suppressed.

The upper portion of the vacuum vessel 21 where the plurality of shower apertures 25 are formed is covered with a cover 27 which has a gas supply opening 26 at its center so as to form a gas dispersion chamber 28 between the cover 27 and the upper portion of the vacuum vessel 21 where the plurality of shower apertures 25 are formed so that a gas supplied from the gas supply opening 26 is spread over the plurality of the shower apertures 25. Additionally, in the case of using two or more types of gases, the gas dispersion chamber 28 also serves as a function of mixing the gases. The gas supply opening 26 is connected to a gas introduction system 41. By a flow rate control portion (not shown) provided in this gas introduction system 41, a flow rate of the gas supplied from the gas supply opening 26 can be controlled.

As a discharger for causing a gas supplied into the vacuum vessel 21 to discharge, a tube-shaped discharge electrode 29 disposed outside of the vacuum vessel 21 so as to surround the plasma generation region 20, and a magnetic force line generator 31 for generating such magnetic force lines H as to have a magnetic field substantially parallel to an axial direction of the tube-shaped discharge electrode 29, along a surface of the tube-shaped discharge electrode 29, are provided.

The above-mentioned discharge electrode 29 is provided on an outer wall of the vacuum vessel 21, and generates a high-frequency electric field for a magnetron discharge. This discharge electrode 29 which comprises, for example, a tube-shaped ring electrode, is composed of aluminum or a material which have alumina and the like generated by applying a surface treatment on surface of aluminum.

The magnetic force line generator 31 is also provided on the outer wall of the vacuum vessel 21. This magnetic force line generator 31 comprises a pair of upper and lower permanent magnets 30 which are formed in a ring shape. These permanent magnets 30 are disposed in a ring shape so as to surround the tube-shaped discharge electrode 29. The pair of permanent magnets 30 which are magnetized in a radial direction thereof, are magnetized in the opposite direction to each other. For example, if an inside of the upper magnet 30 is the north pole, an inside of the lower magnet 30 is the south pole. As a result, such magnetic force lines H as to have a magnetic field which comprises a component substantially parallel to the axial direction of the tube-shaped discharge electrode 29 are generated in a direction of a cylinder axis along an inner surface of the tube-shaped discharge electrode 29.

At a lower portion of the vacuum vessel 21, there is provided a susceptor 33 on which the substrate to be treated W such as a silicon wafer and the like is loaded. The susceptor 33 is grounded so as to be a lowest potential, and high frequency electric power is applied between this susceptor 33 and the tube-shaped discharge electrode 29. The susceptor 33 is disposed in a position facing the above-mentioned plurality of shower apertures 25.

The substrate to be treated W is supported on the susceptor 33. As a method for heating the substrate to be treated W. for example, there is a method for heating the substrate W using the susceptor 33 in which a resistance heater is embedded, a method for heating the substrate W by infrared radiation using a lamp, a method for heating the substrate W using energy of a plasma which is allowed to stand by use of an inert gas, or the like. Here, in the susceptor 33, there is provided a ceramic heater (not shown) made of a material having high temperature resistance and fluorine base plasma resistance such as aluminum nitride so as to permit a high temperature heating so that it is possible to meet a process in which a high substrate temperature is required during film formation of a low hydrogen nitride film and the like. The ceramic heater is adapted to be capable of controlling a temperature of the substrate to be treated W with a heat controller 44, and has heating ability to a temperature of the order of 500° C.

By composing the vacuum vessel 21 and heater of ceramic, alumina or quartz, an amount of metal contamination absorbed into a film is reduced when forming a silicon nitride film.

The lower vessel 23 which seals the lower opening portion 24 of the vacuum vessel 21 is provided with an exhaustion opening 34 which exhausts a gas within the vacuum vessel 21 in the direction of an arrow. The exhaustion opening 34 is in communication with a vacuum exhaustion system 42 and is adapted to be capable of controlling a pressure in the vacuum vessel 21 by a pressure control portion provided in the vacuum exhaustion system 42.

The above-mentioned tube-shaped discharge electrode 29 is connected to a high-frequency electric power application system 43. The high-frequency electric power application system 43 includes a high-frequency electric power source 35 and is adapted to supply high-frequency electric power (RF electric power) to the discharge electrode 29 via a matching circuit 36. The above-mentioned high-frequency electric source 35 is controlled by an electric power source controlling portion 39 and is adapted to be capable of varying the high-frequency electric power which is supplied to the discharge electrode 29. The high-frequency electric power source 35 can supply high-frequency electric power greater than 1 kW and is capable of supplying high-frequency electric power up to 3 kW as ability.

Additionally, over the upper vessel 22 of the vacuum vessel 21, there is provided a RF cover 37 which covers the upper vessel 22 and is adapted to shield the tube-shaped discharge electrode 29.

As mentioned above, because the tube-shaped discharge electrode 29 is located at an outside of the vacuum vessel 21, the tube-shaped discharge electrode 29 does not constitute the vacuum vessel wall. As a result, in contrast to a tube-shaped discharge electrode interposed in the vacuum vessel 21 via an insulation ring, there is no need for a sealing member between the vacuum vessel wall and the insulation ring, nor between the insulation ring and the tube-shaped discharge electrode. As a result, the number of the parts can be reduced so as to provide easy assembling of the apparatus so that the manufacturing cost of the apparatus can be reduced.

Additionally, sealing portions are restricted to one portion between the upper vessel 22 and the lower vessel 23 thereby making it possible to substantially reduce the sealing portions so that a high vacuum in the vacuum vessel 21 can be achieved. As a result, pressure retention in the vacuum vessel 21 can be obtained in an extremely broad pressure range of 0.1 Pa to 80 Pa. Accordingly, for example, a high-density plasma can be generated, at a low pressure, thereby enabling high-quality and high-speed film formation so that embedding film formation and the like become possible.

Moreover, in a semiconductor manufacturing process, use of a vacuum vessel made of metal results in a metal contamination concentration of 5×10¹⁰. which does not meet a metal contamination concentration 5×10⁵ which customers demand. In this respect, in the present embodiment, a dielectric such as quartz, aluminum and the like is used as the vacuum vessel 21 to allow the vacuum vessel wall which comes into contact with a plasma to be a dielectric so that plasma damage to the vacuum vessel wall by the plasma is small compared to the metal vacuum vessel thereby making it possible to substantially suppress the metal contamination generated from the vacuum vessel wall. As a result, the metal contamination generated on a surface of the substrate to be treated within the vacuum vessel due to the plasma damage can be extremely reduced thereby making it possible to sufficiently meet the above-mentioned metal contamination concentration which customers demand.

Furthermore, because the vacuum vessel 21 comprises the upper vessel 22 and the lower vessel 23 to form the upper vessel 22 which is to be a body of the vacuum vessel 21 into one piece structure of a dome shape without a juncture except that the structure is opened at its lower end, the number of the parts of the apparatus can be substantially reduced so as to provide easier assembling of the vacuum vessel 21 so that the manufacturing cost of the apparatus can be lower. Further, because the vacuum vessel 21 is composed of a dielectric, there is no need to allow a portion of the vacuum vessel to be an electric conductive material such as a chamber made of aluminum thereby making it possible to prevent the plasma generation region from being narrowed so as to improve the plasma treatment efficiency.

In addition, the vacuum vessel 21 is provided with the plurality of shower apertures 25 which uniformly supply a gas and the susceptor 33 on which the substrate to be treated W is loaded is provided at a position facing the shower apertures 25 so that a gas flow becomes uniform so as to further enhance uniformity of the plasma treatment of the substrate to be treated W. In particular, if a distance from the gas shower apertures 25 which supply a process gas to the substrate to be treated W is set to be, for example, 10 cm or longer, the distance from the gas shower apertures 25 to the substrate to be treated W is sufficiently long so that the process gas is sufficiently activated to enable a high-speed process.

Additionally, in a construction of FIG. 1. In particular, if vertical location of the tube-shaped discharge electrode 29 and the ring-shaped permanent magnets 30 is allowed to be variable within a fixed range, a plasma distribution is adapted to be controllable thereby making it possible to form an optimum plasma distribution on the surface of the substrate to be treated. As a result, the uniformity of the plasma treatment of the substrate to be treated W is improved so that the plasma damage can be restrained.

Next, a flow of the process of the substrate to be treated W will be explained using FIG. 1. By substrate transfer means which is not shown in the drawing, the substrate to be treated W is transferred onto the susceptor 33 within the vacuum vessel 21 and the interior of the vacuum vessel 21 is evacuated to vacuum using the vacuum exhaustion system 42. The substrate to be treated W is then heated by a heater to a temperature suitable for a treatment of the substrate. In this case, because the heating is performed by a ceramic heater made of a material which is resistant to a plasma, the substrate to be treated W can be heated in a broad temperature range of a room temperature to 530° C. Because of this. It is possible to perform a film formation of a nitride film with low hydrogen and the like which have conventionally depended on a thermal CVD apparatus due to requirements of a high temperature. After heating the substrate to be treated W to a prescribed temperature, a gas is supplied at a prescribed flow rate into the vacuum vessel 21 made of a dielectric that is provided with the shower apertures 25 from the gas introduction system via the gas supply opening 26.

At the same time, high-frequency electric power is applied to the tube-shaped discharge electrode 29 from the high-frequency electric power source 35 so that a high-frequency electric field is generated between the discharge electrode 29 and the susceptor 33. In addition to this high-frequency electric field, magnetic force lines H having a magnetic field which comprises a component substantially parallel to the axial direction of the tube-shaped discharge electrode 29 are generated from the magnets 30 and 30 in a direction of a cylinder along an inner surface of the tube-shaped discharge electrode 29. From this high-frequency electric field and the magnetic force lines H, a high-density plasma is generated inside of the plasma treatment region 20 in the vacuum vessel 21.

The principle of the high-density plasma generation can be explained as follows. The gas having been supplied into the vacuum vessel 21 is allowed to discharge by the high-frequency electric power applied between the tube-shaped discharge electrode 29 and the susceptor 33 so that the gas becomes a plasma. The plasma density is highest in the vicinity of the tube-shaped discharge electrode 29. The gases in the plasma state (electric charges) which comprise a radial direction component of the high-frequency electric field generated between the tube-shaped discharge electrode 29 and the susceptor 33 oscillate between the electrode 29 and the susceptor 33. The electric charges oscillating with the radial direction component are trapped by the magnetic force lines H which comprise an axial direction component orthogonal to the radial direction so as to strongly oscillate in the axial direction thereby successively causing other gases to become a plasma by this oscillation so that, as a result, the high-density plasma is generated.

By the plasma being highly densified in this way, the gas becomes a plasma thereby performing a treatment of the substrate to be treated W. In a series of processes from supplying to stopping of the gas and from supplying and stopping of the high-frequency electric power, the interior of the vacuum vessel 21 is maintained at a prescribed pressure by the vacuum exhaustion system 42 including the exhaustion opening 34. A termination of a thin film formation is performed by stopping the high-frequency electric power application. The substrate W having been treated the treatment of which has been finished is transferred to the outside of the vacuum vessel 21 using the substrate transfer means. A subsequent substrate to be treated W is transferred onto the susceptor 33 and the thin film formation is performed in the similar way.

(2) Nitride Film Formation

Here, a specific example will be described wherein a thin film of a nitride compound is formed on an SiO₂ film on an Si wafer using the above-mentioned MMT apparatus. A nitrogen supply source which is supplied into the vacuum vessel 21 from the gas supply opening 26 is an N₂ gas, an NH₃ gas and the like. Film formations were performed by varying any one parameter among parameters of a wafer temperature, an N₂ gas flow rate, a pressure in the vacuum vessel and RF electric power which are film formation parameters, and fixing the other parameters and film formation time at normal values. FIG. 2 to FIG. 6 are the results from these film formations that illustrate a nitride film thickness and film thickness uniformity within a surface of the obtained nitride film. The standard value for each parameter is as follows. These values are current values which users demand.

Wafer temperature: 400° C.

Pressure: 30 Pa

N₂ gas flow rate: 500 sccm

RF electric power: 250W

Film formation time: 30 sec

FIG. 2 illustrates a relation between a wafer temperature (° C.) and a nitride film thickness (angstrom). It was found that when the wafer temperature is set in a range of 240 to 330° C., the nitrification can be most accelerated, the reason of which is however unclear. The nitrify rate linearly decreases when the wafer temperature is set at a temperature lower than 240° C. and decreases in stages when the wafer temperature is set at a temperature higher than 330° C. From this Figure, it is preferable that the wafer temperature be 400° C. or lower.

FIG. 3 illustrates a relation between an N₂ gas flow rate (sccm) and a nitride film thickness (angstrom). It was found that the nitride film thickness hardly changes by the N₂ gas flow rate. Accordingly, controlling the gas flow rate is not so much significant.

FIG. 4 illustrates a relation between a pressure (Pa) and a nitride film thickness (angstrom). With use of a thermal CVD apparatus, the plasma density is generally decreased, when decreasing the pressure, and the nitrify rate is also decreased. For the present MMT apparatus, however, the plasma density is conversely increased when increasing the pressure, and the nitrify rate is also increased. It is supposed that this is because the plasma which is most highly densified in the vicinity of the tube-shaped discharge electrode 29 is diffused to a center of the plasma treatment region as the pressure in the vacuum vessel 21 is decreased so that a more uniform high-density plasma is formed on the wafer. The tendency of the nitrify rate to increase with the decrease in pressure does not change even when the pressure is under 30 Pa. In addition, when the pressure which goes beyond 80 Pa reaches nearly 90 Pa, the discharge becomes unstable.

FIG. 5 illustrates a relation between a high-frequency electric power value (W) and a nitride film thickness (angstrom). The data wherein the RF electric power is from 250W is illustrated, and the nitride film thickness has a tendency to monotonically increase as the RF electric power is increased. This tendency does not change even when the RF electric power is over 400W. Therefore, in order to enhance the nitrify rate, a greater high-frequency electric power value is more preferably applied. In addition, when the RF electric power is under 200W, the discharge becomes unstable.

FIG. 6 illustrates a relation between a pressure (Pa) and film thickness uniformity within a surface (angstrom). The data wherein the pressure is from 3 Pa is illustrated, and the film thickness uniformity within a surface has a tendency to increase as the pressure is increased. This tendency becomes remarkable when the pressure is over 30 Pa. Accordingly, the preferred pressure region of the film thickness uniformity within a surface is from 3 to 30 Pa.

In view of the above explanation, it is found that in order to allow the nitride film thickness formed on the SiO₂ film on the Si wafer to be thicker in the same period of the process time by enhancing the nitrify rate, the wafer temperature is from 240 to 340° C., the N₂ flow rate is an arbitrary flow rate, a lower pressure is more preferable, and a greater RF electric power is more desirable.

Next, using FIG. 7 and FIG. 8, uniformity of a nitride film distribution, and results of a comparison of nitrogen concentrations between the present invention and the conventional example will be explained.

FIG. 7 illustrates a nitride film thickness distribution on the SiO₂ of the Si wafer with φ=200 m. The film thickness was measured with an ellipsometer. The film formation condition of the nitride film is set such that the wafer temperature is 400° C., the pressure is 30 Pa, the N₂ gas flow rate and the RF electric power are the standard values, and the period of the film formation time is 28 sec. The uniformity of the nitride film (nitride compound) was good, that is 1.225%.

FIG. 8 illustrates a nitrogen profile in the SiO₂ film, namely, the concentration of N (atoms %) with regard to the depth. The axis of ordinates which indicates the concentration of N is a logarithmic scale. The film formation condition is that the wafer temperature is 400° C., the pressure is 3 Pa, the N₂ gas flow rate is the standard value, the RF electric power is 1000W, and the period of the treatment time is 1 min. The measurement was made by SIMS (Secondary Ion Mass Spectroscopy). According to this condition, the maximum N concentration of 110% was realized. This N concentration can be varied by changing the film formation condition including the RF electric power and the like.

According to the above-mentioned explanation. It has been suggested that even when the pressure is 30 Pa or lower, the nitrify treatment is well done, however, the actual data has not been shown. Thus, the experimental results will be then shown wherein the pressure is below 30 Pa. FIG. 9 illustrates the uniformity of the nitride film distribution. FIG. 10 illustrates nitrogen concentrations in the conventional example, and it is compared with nitrogen concentrations in the present invention illustrated in FIG. 8.

FIG. 9 shows (a) an SiO₂ film thickness distribution before the nitrify treatment on the Si wafer with φ=200 mm and (b) a nitride film thickness distribution after the nitrify treatment. The film thickness was measured with the ellipsometer. The SiO, film thickness distribution is shown with respect to 1 nm which is a target value. The film formation condition of the nitride film is set such that the high-frequency electric power is 1000W which is on the higher side because the nitride film thickness has a tendency to increase when the high-frequency electric power is increased as mentioned above. The other treatment condition is that the pressure is 30 Pa, the period of the treatment time is 60 sec, and the N₂ gas is the standard value. The uniformity of the nitride film (nitride compound) was good, that is ±2%.

FIG. 10 illustrates results of nitrogen profiles in the SiO₂ film, namely, concentrations of N (atoms·%) in the conventional example wherein the film formation was conducted with a thermal CVD apparatus. The main condition of the film formation of the conventional example is that the wafer temperature is 900° C., and the period of the treatment time is 0.5 min. The nitrogen supply source is an NH₃ gas, an N₂O gas, or an N₂O₂ gas. On the other hand, the condition of the film formation of the present invention is that the wafer temperature is 400° C., the RF electric power is 1000W, the pressure is 3 Pa, and the period of the treatment time is 1 min, as described above. By comparison between the present invention and the conventional example, it is found that the maximum N concentration of 110% has been realized in the present invention whereas conventionally the maximum N concentration was at most 22%.

As described above, in the case of forming a thin film of a nitride film in which nitrogen atoms exist at a high concentration of 1% or higher at a temperature of 400° C. or lower, it is possible to form the thin film of the nitride compound with a low level of metal contamination, by composing the vacuum vessel of ceramic or quartz in the embodiment of the present invention. Moreover, by using a ceramic heater as a heater for heating the substrate to be treated, the temperature of the substrate to be treated can be controlled to be 400° C. or lower. Furthermore, by use of the discharger comprising an electric field and a magnetic field, a good nitride film thickness distribution can be achieved. In particular, by changing the film formation condition, it is possible to allow a nitrogen concentration in the thin film of the nitride compound to be variable within the rage of 1% to 110%. Theoretically, the upper limit of the N concentration can exceed Si concentration. Therefore, the nitride film which has a desirable nitrogen concentration can be formed so that the device quality is improved. Additionally, in a nitrify treatment of a Ta₂O₅ capacitor, the nitrify treatment at a low temperature becomes possible so that a quality of a MOS transistor can be effectively prevented from being deteriorated due to accumulation of a thermal history.

Furthermore, the conventional nitrify method which is a RTN method has required a treatment at a temperature of 800° C. or higher for about 3 min in order to perform nitrification of 20 angstroms, whereas in the embodiment, the treatment becomes possible at a temperature of 400° C. for 30 sec or shorter. Accordingly, when being within the range of the film formation condition of the present invention, the film formation speed is enhanced compared to that of the conventional apparatus.

Moreover, in the above-described embodiment, the high-frequency electric power for discharge is only applied to the tube-shaped discharge electrode along the outer periphery of the vacuum vessel, and in the case that the nitride film uniformity within a substrate surface is further demanded, it is preferable that parallel plate electrodes be constructed from the sesceptor and the shower plate so as to apply a second high-frequency electric power to both the electrodes. As a result, electric charges which are trapped by magnetic force lines can be forcedly oscillated between the electrodes in a direction of a cylinder axis at maximum amplitude so as to generate a plasma with a higher density on a wafer so that the nitride film uniformity within a substrate surface can be more increased.

According to the present invention, a nitrogen concentration in a thin film of a nitride compound can be sufficiently increased, and besides, a low temperature nitrify treatment becomes possible. Moreover, because the low temperature nitrify treatment becomes possible, the device quality can be improved.

What is claimed is:

1. A semiconductor manufacturing apparatus for forming a nitride film, comprising:
a vacuum vessel having a plasma treatment region established in an interior thereof for treating a substrate to be treated;
a gas introduction system for introducing a nitrogen or a nitrogen-containing compound gas into said vacuum vessel;
a tube-shaped discharge electrode disposed along an outer periphery of said vacuum vessel for generating an electric field in said plasma treatment region and causing a compound gas introduced into said vacuum vessel to discharge;
a high-frequency electric power application system for applying high-frequency electric power to said tube-shaped discharge electrode to generate said electric field;
a magnetic force line generator, disposed along an outer periphery of said vacuum vessel, that generates magnetic force lines in said plasma treatment region and causing said magnetic force lines to capture electric charges generated by said discharge;
a vacuum exhaustion system for exhausting said vacuum vessel and controlling a pressure in the vacuum vessel;
a heater that heats the substrate to be treated within said vacuum vessel; and
a heat controller that controls said heater such that a temperature of said substrate to be treated is 400° C. or lower.

2. A semiconductor manufacturing apparatus for forming a nitride film, comprising:
a vacuum vessel having a plasma treatment region established in an interior thereof for treating a substrate to be treated;
a gas introduction system for introducing a nitrogen or a nitrogen-containing compound gas into said vacuum vessel;
a tube-shaped discharge electrode disposed along an outer periphery of said vacuum vessel for generating an electric field in said plasma treatment region and causing a compound gas introduced into said vacuum vessel to discharge;
a high-frequency electric power application system for applying high-frequency electric power to said tube-shaped discharge electrode to generate said electric field;
a magnetic force line generator, disposed along an outer periphery of said vacuum vessel, that generates magnetic force lines in said plasma treatment region and causing said magnetic force lines to capture electric charges generated by said discharge;
a vacuum exhaustion system for exhausting said vacuum vessel and controlling a pressure in the vacuum vessel such that the pressure in the vacuum vessel is 80 Pa or lower;
a heater that heats the substrate to be treated within said vacuum vessel; and
a heat controller that controls a temperature of said substrate to be treated by controlling said heater.
